(19) United States
(12) Patent Application Publication
(10) Pub. No.: US 2023/0058195 A1
(43) Pub. Date: Feb. 23, 2023

(54) SEMICONDUCTOR DEVICE

(71) Applicant: EPISTAR CORPORATION, Hsinchu (TW)

(72) Inventors: Shih-Nan YEN, Hsinchu (TW); Ming-Ta CHIN, Hsinchu (TW); Yi-Ching LEE, Hsinchu (TW); Cheng-Long YEH, Hsinchu (TW)

(21) Appl. No.: 17/892,814

(22) Filed: Aug. 22, 2022

(30) Foreign Application Priority Data
Aug. 23, 2021 (TW) 110131037

(51) Int. Cl. H01L 33/30; H01L 33/06; H01L 33/22

(52) U.S. Cl. CPC H01L 33/305; H01L 33/06; H01L 33/22

(57) ABSTRACT

A semiconductor device is provided, which includes a first semiconductor structure, a second semiconductor structure, and an active region. The first semiconductor structure includes a first semiconductor layer which includes a first dopant and a second dopant. The second semiconductor structure is located on the first semiconductor structure and includes the first dopan. The active region is located between the first semiconductor structure and the second semiconductor structure and includes the first dopant. The first dopant and the second dopant have different conductivity types.

### CROSS REFERENCE TO RELATED APPLICATIONS

This application claims the right of priority based on TW application Serial No. 110131037, filed on Aug. 23, 2021, which is incorporated by reference herein in their entirety.

### FIELD OF DISCLOSURE

The present disclosure relates to a semiconductor device, in particular, to a semiconductor optoelectronic device such as a light-emitting device (such as a light-emitting diode (LED)).

### BACKGROUND OF THE DISCLOSURE

A group III-V semiconductor material containing a group III element and a group V element may be applied to various optoelectronic devices, such as light emitting diodes (LEDs), laser diodes (LDs), photoelectric detectors, solar cells or power devices (such as switches or rectifiers). These optoelectronic devices can be applied in various fields, such as illumination, medical care, display, communication, sensing, or power supply system. For example, in light-emitting devices, LEDs have low energy consumption and long operating lifetime, and are widely used.

### SUMMARY OF THE DISCLOSURE

The present disclosure provides a semiconductor device. The semiconductor device includes a first semiconductor structure, a second semiconductor structure, and an active region. The first semiconductor structure includes a first semiconductor layer which includes a first dopant and a second dopant. The second semiconductor structure is located on the first semiconductor structure and includes the first dopant. The active region is located between the first semiconductor structure and the second semiconductor structure and includes the first dopant. The first dopant and the second dopant have different conductivity types.

### BRIEF DESCRIPTION OF THE DRAWINGS

FIG. 1A shows a schematic top view of a semiconductor device in accordance with an embodiment of the present disclosure.

FIG. 1B and FIG. 1C show a schematic sectional view and a partial enlarged view of a semiconductor device in accordance with an embodiment of the present disclosure.

FIG. 2A shows a schematic sectional view of a semiconductor device in accordance with an embodiment of the present disclosure.

FIG. 2B shows a schematic sectional view of a semiconductor device in accordance with an embodiment of the present disclosure.

FIG. 3A is a graph showing the relationship between concentrations of elements and depths in a portion of a light-emitting device in accordance with an embodiment of the present disclosure.

FIG. 3B is a graph showing the relationship between concentrations of elements and depths in a portion of a light-emitting device in accordance with an embodiment of the present disclosure

FIG. 4A shows a schematic top view of a semiconductor device in accordance with an embodiment of the present disclosure.

FIG. 4B shows a schematic sectional view of a semiconductor device in accordance with an embodiment of the present disclosure.

FIG. 5A shows a schematic sectional view of a semiconductor component in accordance with an embodiment of the present disclosure.

FIG. 5B shows a schematic sectional view of a semiconductor component in accordance with an embodiment of the present disclosure.

FIG. 6 shows a schematic sectional view of a semiconductor component in accordance with an embodiment of the present disclosure.

### DETAILED DESCRIPTION OF THE DISCLOSURE

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

In the present disclosure, if not otherwise specified, the general formula InGaP represents Inₓ₀Ga₁₋ₓ₀P, wherein 0<x0<1; the general formula AlInP represents Alₓ₁In₁₋ₓ₁P, wherein 0<x1<1; the general formula AlGaInP represents Alₓ₂Gaₓ₃In₁₋ₓ₂₋ₓ₃P, wherein 0<x2<1 and 0<x3<1; the general formula InGaAsP represents Inₓ₄Ga₁₋ₓ₄Asₓ₅P₁₋ₓ₅, wherein 0<x4<1 , 0<x5<1; the general formula AlGaInAs represents Alₓ₆Gaₓ₇In₁₋ₓ₆₋ₓ₇As, wherein 0<x6<1 and 0<x7<1; the general formula InGaAs represents Inₓ₈Ga₁₋ₓ₈As, wherein 0<x8<1; the general formula AlGaAs represents Alₓ₉Ga₁₋ₓ₉As, wherein 0<x9<1; the general formula InGaN represents Inₓ₁₀Ga₁₋ₓ₁₀N, wherein 0<x10<1; the general formula AlGaN represents Alₓ₁₁Ga₁₋ₓ₁₁N, wherein 0<x11<1; the general formula AlGaAsP represents Alₓ₁₂Ga₁₋ₓ₁₂Asₓ₁₃P₁₋ₓ₁₃, wherein 0<x12<1 and 0<x13<1; the general formula InGaAsN represents Inₓ₁₄Ga₁₋ₓ₁₄Asₓ₁₅N₁₋ₓ₁₅, wherein 0<x14<1 and 0<x15<1; the general formula AlInGaN represents Alₓ₁₆Inₓ₁₇Ga₁₋ₓ₁₆₋ₓ₁₇N, wherein 0<x16<1 and 0<x17<1. The content of each element may be adjusted for different purposes, for example, for adjusting the energy gap, or the peak wavelength or dominant wavelength when the semiconductor device is a light-emitting device. However, the present disclosure is not limited thereto.

For example, the semiconductor device of the present disclosure is a light-emitting device (such as a light-emitting diode or a laser diode), a light absorbing device (such as a photo-detector) or a non-optoelectronic device. Analysis of the composition and/or dopant contained in each layer of the semiconductor device of the present disclosure may be conducted by any suitable method such as a secondary ion mass spectrometer (SIMS). A thickness of each layer may be obtained by any suitable method, such as a transmission electron microscopy (TEM) or a scanning electron microscope (SEM).

A person skilled in the art can realize that addition of other components based on a structure recited in the following embodiments is allowable. For example, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not physically contact each other. In addition, it should be realized that a positional relationship of a layer/structure may be altered when being observed in different orientations.

Furthermore, in the present disclosure, a description of “a layer/structure only includes M material” means the M material is the main constituent of the layer/structure; however, the layer/structure may still contain a dopant or unavoidable impurities.

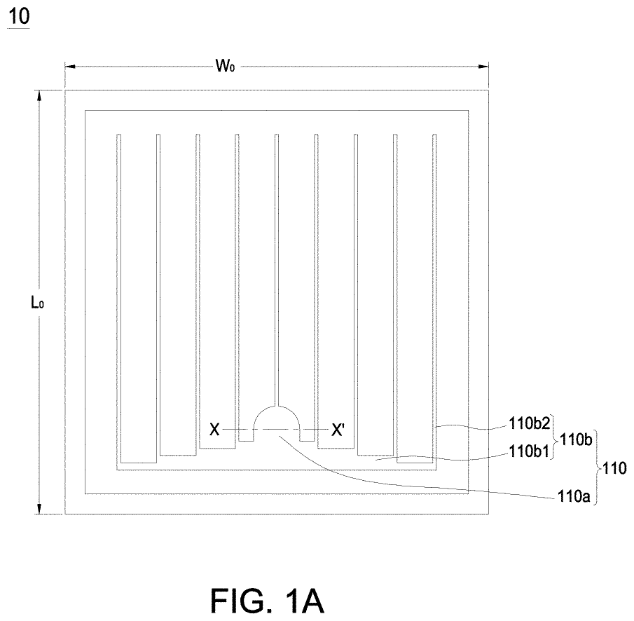

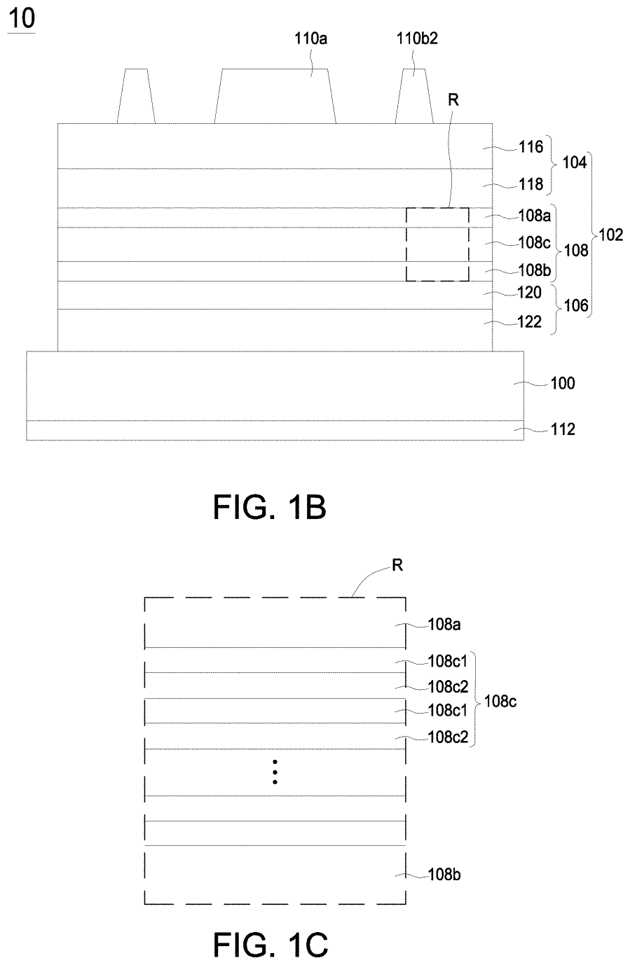

FIG. 1A shows a schematic top view of a semiconductor device 10 in accordance with an embodiment of the present disclosure. FIG. 1B shows a schematic sectional view of the semiconductor device 10 along the line X-X′ in FIG. 1A. FIG. 1C shows a partial enlarged view of a region R in the semiconductor device 10 shown in FIG. 1B.

As shown in FIG. 1A, when viewed from above, the semiconductor device 10 may have a length L₀ and a width W₀. The length L₀ and the width W₀ may be less than or equal to 500 μm, such as less than or equal to 450 μm, 400 μm, 350 μm, 300 μm, 250 μm, 200 μm, 150 μm, 100 μm, 50 μm, 30 μm or 10 μm, and may be greater than or equal to 1 μm. When viewed from above, the semiconductor device 10 may have a rectangular or circular shape. In an embodiment, the length L₀ and the width Wo of the semiconductor device 10 may be approximately equal so that the shape of the semiconductor device 10 is a square. In an embodiment, when viewed from above, the area of the upper surface (L₀*W₀) of the semiconductor device 10 is less than 10000 μm². For example, the area of the upper surface is in the range of 1 μm² to 5000 μm² (such as 100 μm², 625 μm², 1250 μm², 2000 μm² or 2500 μm²).

As shown in FIGS. 1A and 1B, the semiconductor device 10 includes a base 100, an epitaxial structure 102, a first electrode 110, and a second electrode 112. The epitaxial structure 102 is located on the base 100. The epitaxial structure 102 includes a first semiconductor structure 104, a second semiconductor structure 106, and an active region 108 located between the first semiconductor structure 104 and the second semiconductor structure 106. The first electrode 110 is located on the epitaxial structure 102, and the second electrode 112 is located under the base 100. As shown in FIG. 1A, the first electrode 110 may include an electrode pad 110a and an extension electrode 110b connected to the electrode pad 110a. In this embodiment, the extension electrode 110b includes a first extension portion 110b1 and a second extension portion 110b2. The first extension portion 110b1 is in direct contact with the electrode pad 110a, and the second extension portion 110b2 is in direct contact with the first extension portion 110b1 and may extend in a direction perpendicular to the first extension portion 110b1. The first extension portion 110b1 may have a width greater than or equal to the width of the second extension portion 110b2. In this embodiment, when viewed from above, the width of the first extending portion 110b1 is gradually changed. For example, the width is gradually increased in a direction toward the electrode pad 110a, and is gradually decreased in a direction away from the electrode pad 110a. In an embodiment, the semiconductor device 10 may only have one electrode pad 110a, but it is not limited thereto, the semiconductor device 10 may also have more than two electrode pads 110a.

The base 100 may include conductive or insulating materials. The conductive materials may include gallium arsenide (GaAs), indium phosphide (InP), silicon carbide (SiC), gallium phosphide (GaP), zinc oxide (ZnO), gallium nitride (GaN), aluminum nitride (AlN), germanium (Ge) or silicon (Si). The insulating material may include sapphire. In an embodiment, the base 100 is a growth substrate, that is, the epitaxial structure 102 can be formed on the base 100 by an epitaxial method such as metal-organic chemical vapor deposition (MOCVD). In an embodiment, the base 100 is a bonding substrate instead of a growth substrate, and the base 100 can be bonded to the epitaxial structure 102 by an adhesive material layer (not shown).

The first semiconductor structure 104 and the second semiconductor structure 106 may have different conductivity types. For example, the first semiconductor structure 104 is n-type and the second semiconductor structure 106 is p-type, or the first semiconductor structure 104 is p-type and the second semiconductor structure 106 is n-type. Thereby, the first semiconductor structure 104 and the second semiconductor structure 106 can respectively provide electrons and holes, or holes and electrons. The first semiconductor structure 104, the second semiconductor structure 106, and the active region 108 may include an III-V semiconductor material. The III-V semiconductor material may include aluminum (Al), gallium (Ga), arsenic (As), phosphorus (P), nitrogen (N), or indium (In). In an embodiment, the first semiconductor structure 104, the second semiconductor structure 106, and the active region 108 may not contain nitrogen (N). Specifically, the III-V semiconductor material can be a binary compound semiconductor (such as GaAs, GaP or GaN), a ternary compound semiconductor (such as InGaAs, AlGaAs, InGaP, AlInP, InGaN or AlGaN) or a quaternary compound semiconductor (such as AlGaInAs, AlGaInP, AlInGaN, InGaAsP, InGaAsN or AlGaAsP). In an embodiment, the active region 108 only include a ternary compound semiconductor (such as InGaAs, AlGaAs, InGaP, AlInP, InGaN, or AlGaN) or a quaternary compound semiconductor (such as AlGaInAs, AlGaInP, AlInGaN, InGaAsP, InGaAsN, or AlGaAsP).

The epitaxial structure 102 may include a double heterostructure (DH), a double-side double heterostructure (DDH) or a multiple quantum well (MQW) structure. According to an embodiment, when the semiconductor device 10 is a light-emitting device, the active region 108 may emit a light during operation of the semiconductor device 10. The light includes visible light or invisible light. The light emitted by the semiconductor device 10 is determined by the material composition of the active region 108. For example, when the material of the active region 108 includes InGaN, it may emit a blue light with a peak wavelength of 400 nm to 490 nm, a deep blue light or a green light with a peak wavelength of 490 nm to 550 nm; when the material of the active region 108 includes AlGaN, it may emit ultraviolet light with a peak wavelength of 250 nm to 400 nm; when the material of the active region 108 includes InGaAs, InGaAsP, AlGaAs or AlGaInAs, it may emit an infrared light with a peak wavelength of 700 to 1700 nm; when the material of the active region 108 includes InGaP or AlGaInP, it may emit a red light with a peak wavelength of 610 nm to 700 nm, or a yellow light with a peak wavelength of 530 nm to 600 nm.

In an embodiment, the active region 108 may include a first confinement layer 108a, a second confinement layer 108b, and one or more semiconductor stacks 108c between the first confinement layer 108a and the second confinement layer 108b. Each semiconductor stack 108c includes a barrier layer 108c1 and a well layer 108c2. In an embodiment, the number of the semiconductor stacks 108c may be greater than or equal to two. In an embodiment, the number of the semiconductor stacks 108c may be 20 or less, and may be 10 or less. For example, the number of the semiconductor stacks 108c is 3, 4, 5, 6, 7, 8, 9, 10, 11, 12, 13, 14, 15, 16, 17, 18, or 19. In an embodiment, when the active region 108 includes five or less semiconductor stacks 108c (i.e., five or less barrier layers 108c1 and five or less well layers 108c2), the semiconductor device 10 can have a relatively high quantum efficiency, especially when the semiconductor device 10 is operated at a low current density (such as 1 A/cm² or less) or a low current (such as 10 mA or less). Specifically, the current density can be obtained by dividing the magnitude of the current (unit: ampere (A)) applied to the semiconductor device 10 by a top-view area of the epitaxial structure 102 (unit: cm²). In an embodiment, the top-view area of the epitaxial structure 102 may be in the range of 1 μm² to 2500 μm², such as 50 μm² to 100 μm², 600 μm², 1200 μm², 1500 μm² or 2000 m². When the epitaxial structure 102 has a plurality of areas with different sizes in a top view, the top-view area refers to the largest one of these areas.

The barrier layer 108c1 and/or the well layer 108c2 may include aluminum (Al). In an embodiment, the active region 108 includes n semiconductor stacks 108c and has n barrier layers 108c1 and n well layers 108c2, wherein n is a positive integer (i.e., n barrier layers 108c1 includes a first barrier layer, a second barrier layer . . . and a n-th barrier layer, and n well layers 108c2 includes a first well layer, a second well layer . . . and a n-th well layer). Each barrier layer 108c1 may have a first aluminum content percentage (ai %, wherein i=1, 2 . . . n), and each well layer 108c2 may have a second aluminum content percentage (bi %, wherein i=1, 2 . . . n). For example, the first barrier layer 108c1 has a first aluminum content percentage a1%, the second barrier layer 108c1 has a first aluminum content percentage a2%, and the n-th barrier layer 108c1 has a first aluminum content percentage an %; the first well layer 108c2 has a second aluminum content percentage b1%, the second well layer 108c2 has a second aluminum content percentage b2%, and the n-th well layer 108c2 has a second aluminum content percentage bn %. In an embodiment, the first aluminum content percentages in each barrier layer 108c1 may be the same or different. The difference in aluminum content percentage (Al %) between the barrier layers 108c1 may be between 0 to 1 atom %. In an embodiment, the second aluminum content percentage in each the well layer 108c2 may be the same or different. The difference in aluminum content percentage (Al %) between the well layers 108c2 may be between 0 to 1 atom %.

Specifically, the first and second aluminum content percentages refer to the atomic percentages (atom %) of Al in the barrier layer 108c1 and the well layer 108c2, respectively. For example, the first and second aluminum content percentages can be obtained by analyzing the barrier layer 108c1 and the well layer 108c2 with an Energy Dispersive X-ray spectrometer (EDX). As an example, when the barrier layer 108c1 includes Al_{z1}Ga_{0.5-z1}In_{0.5}P (wherein 0≤z1≤0.5), and the well layer 108c2 includes Al_{z2}Ga_{0.5-z2}In_{0.5}P (wherein 0≤z2≤0.5), z1 and z2 can be obtained from EDX analysis. Here, the first aluminum content percentage (ai %) of the barrier layer 108c1 can be defined as z1*100%, and the second aluminum content percentage (bi %) of the well layer 108c2 can be defined as z2*100%. That is, the aluminum content percentage represents the ratio of Al to the sum of the atomic percentages of all the group III elements. For example, when z1=0.3, it means that the first aluminum content percentage is 30%. In an embodiment, the aluminum content percentages of the barrier layer 108c1 and the well layer 108c2 can also be obtained by a SIMS analysis. In an embodiment, the first aluminum content percentage is greater than the second aluminum content percentage. In an embodiment, the first aluminum content percentage may be in the range of 15% to 50%, such as 20%, 25%, 30%, 35%, 40%, 45% or 50%. In an embodiment, the second aluminum content percentage may be in the range of 0% to 15%, such as 5% or 10%. In an embodiment, when the percentage of the first aluminum content is greater than or equal to 25%, the ability of the barrier layer 108c1 to confine electrons can be further improved, resulting in better quantum efficiency (such as better external quantum efficiency (EQE) or internal quantum efficiency (IQE)). In an embodiment, when the percentage of the first aluminum content is greater than or equal to 35%, a better quantum efficiency can be obtained.

In an embodiment, the active region 108 includes n semiconductor stacks 108c (i.e., n barrier layers 108c1 and n well layers 108c2), wherein n is a positive integer. Each barrier layer 108c1 has a first thickness (t1i, wherein i=1, 2 . . . n), and each well layer 108c2 has a second thickness (t2i, wherein i=1, 2 . . . n). The first thickness may be greater than or equal to the second thickness. The first barrier layer 108c1 has a first thickness t11, the second barrier layer 108c1 has a first thickness t12, the n-th barrier layer 108c1 has a first thickness t1n, the first well layer 108c2 has a second thickness t21, the second well layer 108c2 has a second thickness t22, and the n-th well layer 108c2 has a second thickness t2n. In an embodiment, the first thicknesses of the barrier layers 108c1 may be the same or different, and the thickness difference between the barrier layers 108c1 may be between 0 to 1 nm. In an embodiment, the second thicknesses of the well layers 108c2 may be the same or different, and the thickness difference between the well layers 108c2 may be between 0 to 1 nm. The first thickness and the second thickness may be less than or equal to 200 Å, such as about 150 Å, 100 Å, 50 Å, or 10 Å. In an embodiment, when the thicknesses of the barrier layer 108c1 and the well layer 108c2 are both less than or equal to 200 Å, the semiconductor device 10 may have a better quantum efficiency. In an embodiment, the ratio of the first thickness (t1i) to the second thickness (t2i) is in the range of 2:1 to 40:1. For example, the ratio of the first thickness to the second thickness (t1i/t2i) may be in the range of 10:1 to 35:1. By having a larger first thickness, the ability of the barrier layer 108c1 to confine electrons can be improved. In an embodiment, the first thickness may be in the range of 20 Å to 4000 Å. For example, the first thickness may be greater than or equal to 100 Å and less than or equal to 2000 Å. The second thickness may be in the range of 10 Å to 200 Å, such as 150 Å, 100 Å or 50 Å.

As shown in FIG. 1B, the first semiconductor structure 104 includes a first semiconductor layer 116 and a second semiconductor layer 118. The first semiconductor layer 116 is farther from the active region 108 than the second semiconductor layer 118. In an embodiment, the first semiconductor layer 116 may serve as a window layer (or a light extraction layer) to improve the luminous efficiency of the semiconductor device 10. The thickness of the first semiconductor layer 116 may be greater than, equal to or less than the thickness of the second semiconductor layer 118. In an embodiment, the first semiconductor layer 116 may be the semiconductor layer with the largest thickness in the first semiconductor structure 104. The thickness of the first semiconductor layer 116 may be in the range of 2000 Å to 8000 Å. According to an embodiment, the upper surface of the first semiconductor layer 116 has a roughened structure. The second semiconductor layer 118 may serve as a cladding layer. In this embodiment, the second semiconductor layer 118 is in direct contact with the first confinement layer 108a. The first semiconductor layer 116 and the second semiconductor layer 118 may contain different compound semiconductor materials. In an embodiment, the first semiconductor layer 116 includes a binary III-V semiconductor material (such as GaAs, GaP, or GaN), and the second semiconductor layer 118 includes a ternary III-V semiconductor material (such as InGaAs, AlGaAs, InGaP, AlInP, InGaN or AlGaN) or a quaternary III-V semiconductor material (such as AlGaInAs, AlGaInP, AlInGaN, InGaAsP, InGaAsN or AlGaAsP).

In an embodiment, the first semiconductor structure 104 includes a first dopant and a second dopant different from the first dopant. Specifically, the first semiconductor layer 116 and/or the second semiconductor layer 118 may contain the first dopant and the second dopant. In an embodiment, the second dopant is continuously distributed in the first semiconductor structure 104 (such as the first semiconductor layer 116 and the second semiconductor layer 118). For example, in a SIMS analysis of the semiconductor structure 104, the signal of the second dopant can be obtained at each depth position in the semiconductor structure 104. With respect to the first semiconductor structure 104 (i.e., the first semiconductor layer 116 and the second semiconductor layer 118), the first dopant and the second dopant have different conductivity types (such as p-type and n-type, or n-type and p-type, respectively). In an embodiment, the first semiconductor structure 104 includes the first dopant and the second dopant, and the conductivity type of the first semiconductor structure 104 is n-type. In an embodiment, the first semiconductor structure 104 includes the first dopant and the second dopant, and the conductivity type of the first semiconductor structure 104 is p-type.

According to an embodiment, the first dopant has a first maximum concentration (C1) in the first semiconductor structure 104, and the second dopant has a second maximum concentration (C2) in the first semiconductor structure 104 greater than the first maximum concentration (C1). In an embodiment, the first maximum concentration (C1) and the second maximum concentration (C2) are located at or near an interface between the first semiconductor layer 116 and the second semiconductor layer 118. In an embodiment, the conductivity type of the first semiconductor structure 104 is determined by the concentrations of the first dopant and the second dopant. For example, when the second dopant is an n-type dopant and the concentration of the second dopant in the first semiconductor structure 104 is greater than that of the first dopant, the conductivity type of the first semiconductor structure 104 is n-type. By contrast, when the second dopant is a p-type dopant and the concentration of the second dopant in the first semiconductor structure 104 is greater than that of the first dopant, the conductivity type of the first semiconductor structure 104 is p-type. In an embodiment, according to the concentration relationship between the first and second dopants, the first semiconductor structure 104 can be divided into a first region and a second region. The concentration of the second dopant is greater than that of the first dopant in the first region, and the concentration of the second dopant is smaller than the concentration of the first dopant in the second region. In this case, when the second dopant is an n-type dopant, the conductivity type of the first region in the first semiconductor structure 104 can be n-type, and the conductivity type of the second region can be p-type; by contrast, when the second dopant is a p-type dopant, the conductivity type of the first region in the first semiconductor structure 104 may be p-type, and the conductivity type of the second region may be n-type. The first region and the second region do not overlap. The first region (or the second region) may be entirely located in the first semiconductor layer 116 or the second semiconductor layer 118. Alternatively, the first region (or the second region) may be in the first semiconductor layer 116 and the second semiconductor layer 118. For example, the first region may have a first part in the first semiconductor layer 116 and a second part in the second semiconductor layer 118 (i.e., the first region extends across the interface between the first semiconductor layer 116 and the second semiconductor layer 118), and the rest portion of the first semiconductor structure 104 that does not overlap with the first region belongs to the second region. In an embodiment, the first dopant and the second dopant may be group II, group IV or group VI elements in the periodic table of elements. In an embodiment, the first dopant and the second dopant are group VI and group II elements, respectively. Specifically, the first dopant and the second dopant can be respectively C, Zn, Si, Ge, Sn, Se, Mg or Te.

In an embodiment, the first semiconductor structure 104 may further include a superlattice structure (not shown) located between the first semiconductor layer 116 and the second semiconductor layer 118 to further improve the current distribution. The superlattice structure can be made by alternately stacking two kinds of III-V compound semiconductor layers that contain different materials. According to an embodiment, the materials of the superlattice structure are different from the material of the barrier layer 108c1 or the well layer 108c2. In an embodiment, the superlattice structure may include binary compound semiconductors and ternary compound semiconductors that are alternately stacked, such as GaN and AlGaN. In an embodiment, the superlattice structure may include ternary compound semiconductors and quaternary compound semiconductors that are alternately stacked, such as AlInP and AlGaInP.

As shown in FIGS. 1B and 1C, in the active region 108, the first confinement layer 108a and the second confinement layer 108b are in direct contact with the semiconductor stack(s) 108c. The first confinement layer 108a and the second confinement layer 108b may respectively include an III-V semiconductor material such as a ternary compound semiconductor (such as InGaAs, AlGaAs, InGaP, AlInP, InGaN or AlGaN) or a quaternary compound semiconductor (such as AlGaInAs, AlGaInP, AlInGaN, InGaAsP, InGaAsN or AlGaAsP). In an embodiment, the first confinement layer 108a and the second confinement layer 108b include the same semiconductor material as the barrier layer 108c1. The first confinement layer 108a and/or the second confinement layer 108b may include aluminum. The first confinement layer 108a may have a third aluminum content percentage, and the second confinement layer 108b may have a fourth aluminum content percentage. As described above, the aluminum content percentage here means the ratio of Al to the sum of the atomic percentages of all the three group elements. In an embodiment, the third aluminum content percentage and the fourth aluminum content percentage are both greater than the second aluminum content percentage. In an embodiment, the third aluminum content percentage and the fourth aluminum content percentage are both greater than or equal to the first aluminum content percentage. In an embodiment, the first confinement layer 108a may have a third thickness (t3), and the second confinement layer 108b may have a fourth thickness (t4). The third thickness and the fourth thickness may be the same or different. In an embodiment, the third thickness is greater than or equal to the second thickness and the fourth thickness is greater than or equal to the second thickness, thereby enhancing the ability of the first confinement layer 108a and the second confinement layer 108b to confine electrons. In an embodiment, the ratio of the third thickness to the first thickness or the second thickness (i.e., t3/t1i or t3/t2i) is in the range of 1.5:1 to 10:1, such as 2:1, 3:1, 4 :1, 5:1, 6:1, 7:1, 8:1, or 9:1. In an embodiment, the ratio of the fourth thickness to the first thickness or the second thickness (i.e., t4/t1i or t4/t2i) is in the range of 1.5:1 to 10:1, such as 2:1, 3:1, 4 :1, 5:1, 6:1, 7:1, 8:1, or 9:1. In an embodiment, when t3/t1i, t3/t2i, t4/t1i or t4/t2i falls within the above ranges, the electron confinement capability of the first confinement layer 108a and the second confinement layer 108b can be further enhanced.

In an embodiment, the active region 108 optionally includes the first dopant. The first dopant may be an n-type or p-type dopant with respect to the active region 108. In an embodiment, the active region 108 and the first semiconductor structure 104 have the same conductivity type. In an embodiment, the doping concentration of the first dopant in the active region 108 is greater than or equal to 1×10¹⁶/cm³. In an embodiment, the doping concentration of the first dopant in the active region 108 is less than 1×10¹⁹/cm³. Specifically, the doping concentration of the first dopant in the active region 108 may be in the range of 1×10¹⁶/cm³ to 5×10¹⁶/cm³, 1×10¹⁷/cm³, 5×10¹⁷/cm³, 1×10¹⁸/cm³ or 5×10¹⁸/cm³. The first dopant has a third maximum concentration (C3) in the active region 108, and the third maximum concentration (C3) may be greater than, less than, or equal to the first maximum concentration (C1). In an embodiment, the first dopant is continuously distributed in the active region 108. For example, in a SIMS analysis of the active region 108, the signal of the first dopant can be obtained at each depth position in the active region 108. Specifically, in an embodiment, in the SIMS analysis, the first dopant is distributed between a surface of the second confinement layer 108b away from the semiconductor stack(s) 108c and the interface between the semiconductor stack(s) 108c and the first confinement layer 108a, and is present in each barrier layer 108c1 and each well layer 108c2 of the active region 108. For example, in the active region 108, the first dopant has a doping concentration of not less than 1×10¹⁶/cm³ and less than 1×10¹⁸/cm³.

In an embodiment, in the semiconductor stack 108c closest to the second confinement layer 108b, the doping concentration of the first dopant may be not less than 1×10¹⁶/cm³ and not greater than 1×10¹⁸/cm³. In an embodiment, in the semiconductor stack 108c closest to the first confinement layer 108a, the doping concentration of the first dopant may be not less than 1×10¹⁶/cm³ and not greater than 1×10¹⁷/cm³. In an embodiment, the doping concentration of the first dopant in the semiconductor stack 108c closest to the second confinement layer 108b is greater than or equal to the doping concentration of the first dopant in the semiconductor stack 108c closest to the first confinement layer 108a. In an embodiment, the first dopant is distributed in the first confinement layer 108a, the second confinement layer 108b and the semiconductor stack(s) 108c. In an embodiment, the doping concentration of the first dopant in the second confinement layer 108b is greater than or equal to the doping concentration of the first dopant in the semiconductor stack(s) 108c. In an embodiment, the doping concentration of the first dopant in the semiconductor stack(s) 108c is greater than or equal to the doping concentration of the first dopant in the first confinement layer 108a. In an embodiment, the doping concentration of the first dopant decreases gradually from the second confinement layer 108b to the first confinement layer 108a. Specifically, In an embodiment, the first dopant in the second confinement layer 108b may have a minimum doping concentration 51, the first dopant in the first confinement layer 108a may have a minimum doping concentration S2, and the first dopant in the semiconductor stack(s) 108c may have a minimum doping concentration S3, where S1≥S3≥S2. The minimum doping concentrations S1, S2, and S3 may be the minimum concentrations of the first dopant in the second confinement layer 108b, the first confinement layer 108a, and the semiconductor stack(s) 108c, respectively. For example, when analyzing the concentration curve of the first dopant by SIMS, the minimum doping concentrations mentioned above may correspond to the lowest trough positions of the concentration curve of the first dopant in the second confinement layer 108b, the first confinement layer 108a and the semiconductor stack 108c, respectively, in the SIMS analysis result (in the absence of apparent troughs, the lowest trough positions may refer to minimum detectable concentrations of the first dopant).

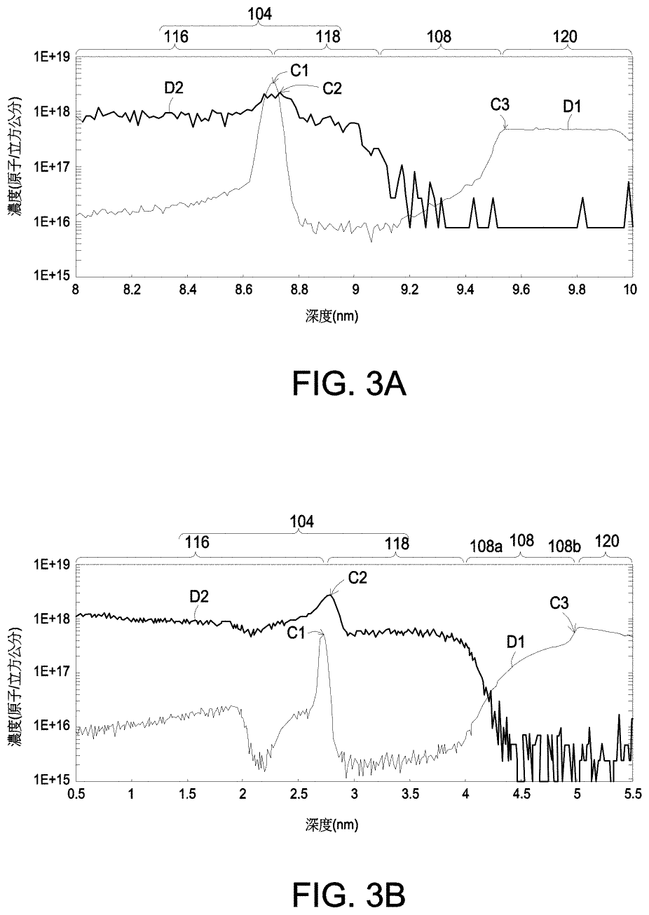

The second dopant may also be distributed in the semiconductor stack 108c and/or the first confinement layer 108a. In an embodiment, the first dopant and the second dopant may coexist in the first confinement layer 108a. In an embodiment, the second dopant in the first confinement layer 108a may have a doping concentration of not less than 1×10¹⁶/cm³, such as in the range of 5×10¹⁶/cm³ to 1×10¹⁸/cm³. In an embodiment, the doping concentration of the second dopant in the second semiconductor layer 118 is greater than the doping concentration of the second dopant in the first confinement layer 108a. According to an embodiment, in the active region 108, the concentration of the first dopant gradually increases and the concentration of the second dopant gradually decreases along the direction from the first confinement layer 108a to the second confinement layer 108b. According to an embodiment, when analyzing the distribution of the first dopant and the second dopant in the epitaxial structure 102, the concentration curves of the first dopant and the second dopant have an intersection in the active region 108 as shown in FIG. 3A or FIG. 3B.

As shown in FIG. 1B, the second semiconductor structure 106 includes a third semiconductor layer 120 and a fourth semiconductor layer 122. The third semiconductor layer 120 is closer to the active region 108 than the fourth semiconductor layer 122. In an embodiment, the fourth semiconductor layer 122 can serve as a window layer (or a light extraction layer) to improve the luminous efficiency of the semiconductor device 10. The thickness of the fourth semiconductor layer 122 may be greater than, equal to or less than the thickness of the third semiconductor layer 120. In an embodiment, the fourth semiconductor layer 122 may be the semiconductor layer with the largest thickness in the second semiconductor structure 106. The third semiconductor layer 120 may serve as a cladding layer. In this embodiment, the third semiconductor layer 120 is in direct contact with the second confinement layer 108b. The third semiconductor layer 120 and the fourth semiconductor layer 122 may contain different compound semiconductor materials. In an embodiment, the third semiconductor layer 120 includes a ternary III-V semiconductor material (such as InGaAs, AlGaAs, InGaP, AlInP, InGaN, or AlGaN), and the fourth semiconductor layer 122 includes a quaternary III-V semiconductor material (such as AlGaInAs, AlGaInP, AlInGaN, InGaAsP, InGaAsN or AlGaAsP). In an embodiment, the second semiconductor structure 106 also includes the first dopant. With respect to the second semiconductor structure 106 (i.e., the third semiconductor layer 120 and the fourth semiconductor layer 122), the first dopant may be an n-type dopant or a p-type dopant. Specifically, the first dopant may be distributed in the third semiconductor layer 120 and the fourth semiconductor layer 122. In an embodiment, the first dopant is continuously distributed in the second semiconductor structure 106. For example, in a SIMS analysis of the second semiconductor structure 106, the signal of the first dopant can be obtained at each depth position in the second semiconductor structure 106. In an embodiment, the first dopant in the third semiconductor layer 120 and/or the fourth semiconductor layer 122 may have a doping concentration of not less than 5×10¹⁶/cm³, such as in the range of 5×10¹⁶/cm³ to 1×10¹⁹/cm³. The first dopant in the third semiconductor layer 120 has a fourth maximum concentration (C4), and the fourth maximum concentration (C4) may be greater than, less than or equal to the first maximum concentration (C1). The first dopant in the fourth semiconductor layer 122 has a fifth maximum concentration (C5), and the fifth maximum concentration (C5) may be greater than, less than or equal to the first maximum concentration (C1). According to an embodiment, the second semiconductor structure 106 may not include the second dopant or only includes a small amount of the second dopant (for example, when analyzing the second semiconductor structure 106 by SIMS, an average concentration of the second dopant in the second semiconductor structure 106 is less than 1×10¹⁶/cm³).

The first electrode 110 and the second electrode 112 provide electrical connections with an external power supply. The materials of the first electrode 110 and the second electrode 112 may be the same or different. For example, the materials of the first electrode 110 and the second electrode 112 may include a metal oxide, a metal or an alloy. The metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). The metal may include germanium (Ge), beryllium (Be), zinc (Zn), gold (Au), platinum (Pt), titanium (Ti), aluminum (Al), nickel (Ni), or copper (Cu). The alloy may include two or more of the above metals, such as germanium gold nickel (GeAuNi), beryllium gold (BeAu), germanium gold (GeAu) or zinc gold (ZnAu).

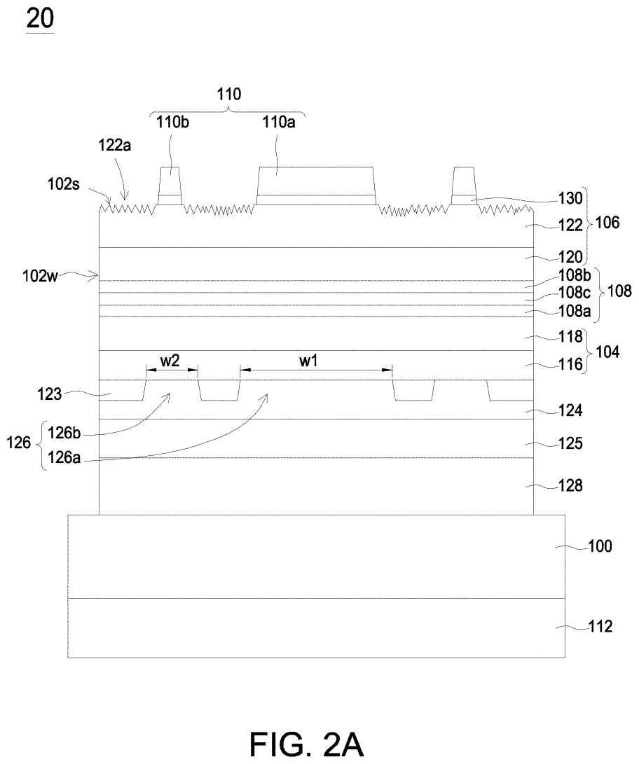

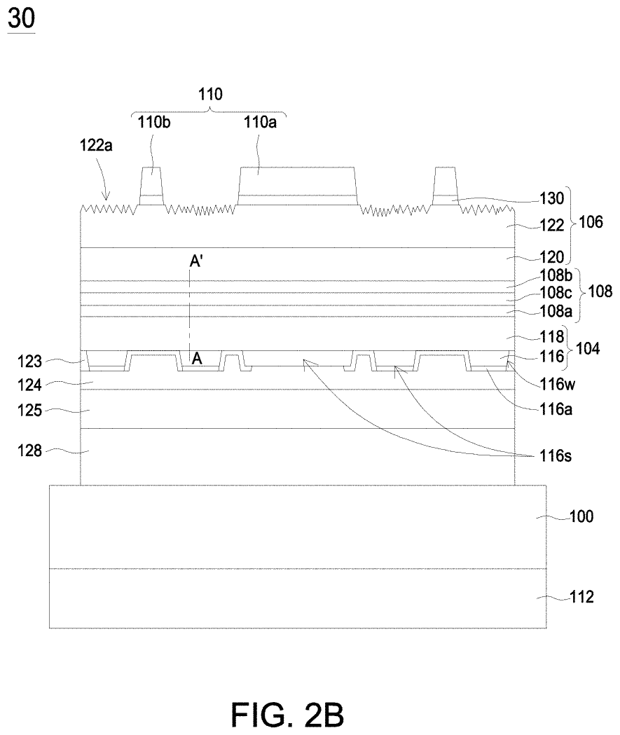

FIG. 2A shows a schematic sectional view of a semiconductor device 20 in accordance with an embodiment of the present disclosure.

The main difference between the semiconductor device 20 of this embodiment and the semiconductor device 10 is that the semiconductor device 20 further includes an insulating structure 123, a conductive layer 124, a reflective layer 125 and a bonding structure 128. The insulating structure 123, the conductive layer 124, the reflective layer 125 and the bonding structure 128 are located between the epitaxial structure 102 and the base 100. In this embodiment, the second semiconductor structure 106 further includes a semiconductor contact layer 130. The semiconductor contact layer 130 may be located between the first electrode 110 and the fourth semiconductor layer 122. In this embodiment, the insulating structure 123 is connected to the first semiconductor structure 104, and the first electrode 110 is located on the second semiconductor structure 106 and is electrically connected to the second semiconductor structure 106. The conductive layer 124 covers the insulating structure 123, the reflective layer 125 covers the conductive layer 124, and the bonding structure 128 is located between the base 100 and the reflective layer 125. In this embodiment, the fourth semiconductor layer 122 is located between the semiconductor contact layer 130 and the third semiconductor layer 120 and the upper surface of the fourth semiconductor layer 122 has a roughened structure 122a. The material of the semiconductor contact layer 130 may be different from the material of the fourth semiconductor layer 122. In some embodiments, the material of the semiconductor contact layer 130 includes a binary III-V semiconductor material, such as GaAs or GaP, and may have the same conductivity type as the second semiconductor structure 106.

The insulating structure 123 may be a patterned dielectric layer. For example, the insulating structure 123 includes silicon nitride (SiNx), aluminum oxide (AlOx), silicon oxide (SiOx), magnesium fluoride (MgFx), or a combination thereof. In an embodiment, x=1.5 or 2. In an embodiment, the insulating structure 123 may be a single layer or multiple layers. When the insulating structure 123 is a single layer, it has an insulating refractive index of less than 2; when the insulating structure 123 includes multiple layers, the refractive index of each layer may be less than 2. In an embodiment, the insulating structure 123 may include a Distributed Bragg Reflector (DBR) structure. The DBR structure may include a plurality of first dielectric layers and a plurality of second dielectric layers alternately stacked, and the first dielectric layers and the second dielectric layers have different refractive indices. In an embodiment, the materials of the first dielectric layer and the second dielectric layer include aluminum oxide (Al₂O₃), silicon dioxide (SiO₂), titanium dioxide (TiO₂) or tantalum oxide (Nb₂O₅). As shown in FIG. 2A, in the cross-sectional view, the shape of the insulating structure 123 includes a plurality of inverted trapezoids, and the lower bases of each trapezoid are in direct contact with the first semiconductor layer 116 in the first semiconductor structure 104. The insulating structure 123 has a plurality of holes 126, the conductive layer 124 can cover the insulating structure 123 and fill the holes 126, and the conductive layer 124 and the epitaxial structure 102 can form a contact region in the holes 126. Thereby, the conductive layer 124 can be electrically connected to the epitaxial structure 102. In this embodiment, the holes 126 include a first hole 126a that vertically overlaps with the electrode pad 110a without overlapping with the extension electrode 110b, and a second hole 126a that vertically overlaps with the extension electrode 110b without overlapping with the electrode pad 110a. As shown in FIG. 2A, a width w1 of the first hole 126a is greater than a width w2 of the second aperture 126b.

The conductive layer 124 may include metal or metal oxide. The metal may include silver (Ag), germanium (Ge), gold (Au), nickel (Ni), or a combination thereof. The metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), indium zinc oxide (IZO), or a combination thereof.

The reflective layer 125 can reflect the light emitted from the active region 108 towards the first electrode 110 to exit the semiconductor device 20. The reflective layer 125 may be conductive and include a semiconductor material, a metal or an alloy. The semiconductor material may include an III-V semiconductor material, such as a binary, ternary or quaternary III-V semiconductor material. The metal may include but not limited to copper (Cu), aluminum (Al), tin (Sn), gold (Au), silver (Ag), lead (Pb), titanium (Ti), nickel (Ni), platinum (Pt) or Tungsten (W). The alloy may include two or more of the above metals. In an embodiment, the reflection layer 125 may include a Distributed Bragg Reflector (DBR) structure. The DBR structure can be formed by alternately stacking two or more semiconductor material layers with different refractive indices, such as AlAs/GaAs, AlGaAs/GaAs or InGaP/GaAs.

The bonding structure 128 connects the base 100 and the reflective layer 125. In an embodiment, the bonding structure 128 may be a single layer or multiple layers (not shown). The bonding structure 128 may be electrically conductive and include a metal oxide, a metal or an alloy. The metal oxide includes but is not limited to indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), gallium phosphide (GaP), indium cerium oxide (ICO), indium tungsten oxide (IWO), indium titanium oxide (ITiO), indium zinc oxide (IZO), indium gallium oxide (IGO), gallium aluminum zinc oxide (GAZO), or a combination thereof. The metal includes but is not limited to copper (Cu), aluminum (Al), tin (Sn), gold (Au), silver (Ag), lead (Pb), titanium (Ti), nickel (Ni), platinum (Pt) or Tungsten (W). The alloy may include two or more of the above metals.

In the embodiment, the second semiconductor structure 106 may include a third dopant that is different from the first dopant and the second dopant. In an embodiment, the third dopant may be distributed in the semiconductor contact layer 130 and/or the fourth semiconductor layer 122. In an embodiment, the third dopant is continuously distributed in the semiconductor contact layer 130. For example, in a SIMS analysis of the semiconductor contact layer 130, the signal of the third dopant can be obtained at each depth position in the semiconductor contact layer 130. In some embodiments, the semiconductor contact layer 130 and/or the fourth semiconductor layer 122 include both the first dopant and the third dopant. In the semiconductor contact layer 130 and/or the fourth semiconductor layer 122, the doping concentration of the third dopant may be higher than the doping concentration of the first dopant. Specifically, the third dopant may be a group II, group IV or group VI element in the periodic table of elements. In an embodiment, the third dopant is selected from C, Zn, Si, Ge, Sn, Se, Mg or Te. In an embodiment, with respect to the second semiconductor structure 106, the first dopant and the third dopant are of the same conductivity type, and the first dopant and the second dopant are of the different conductivity types. For example, with respect to the second semiconductor structure 106, the first dopant and the third dopant are p-type dopants, and the second dopant is an n-type dopant, or the first dopant and the third dopant are n-type dopants, and the second dopant is a p-type dopant. In an embodiment, the first dopant is continuously distributed from the third semiconductor layer 120 to the first confinement layer 108a. For example, when analyzing the third semiconductor layer 120 to the first confinement layer 108a by SIMS, the signal of the first dopant can be obtained at each depth position from the third semiconductor layer 120 to the first confinement layer 108a.

It should be noted that although in FIG. 2A, the second semiconductor structure 106 is located on the active region 108 and the first semiconductor structure 104 is located under the active region 108, in another embodiment, it can also have the following configuration: the second semiconductor structure 106 is located under the active region 108 and is in direct contact with the insulating structure 123 and the conductive layer 124, and the first semiconductor structure 104 is located on the active region 108 and is in direct contact with the first electrode 110. The detailed descriptions of positions, relative relationships and material of other layers or structures as well as structural variations in this embodiment can be referred to the foregoing embodiments and are not repeatedly described herein.

FIG. 2B shows a schematic sectional view of a semiconductor device 30 in accordance with an embodiment of the present disclosure.

The main difference between the semiconductor device 30 and the semiconductor device 20 is that the semiconductor device 30 has a patterned first semiconductor layer 116. In this embodiment, the first semiconductor layer 116 does not overlap the structure of the first electrode 110 in the vertical direction. Specifically, the first semiconductor layer 116 includes a plurality of portions 116s separated from each other, and the insulating structure 123 may be located between two adjacent portions 116s, overlapped with each portion 116s in the horizontal direction, and may conformally cover on the side wall 116w of each portion 116s. As shown in FIG. 2B, the width of each portion 116s may be gradually changed. For example, the width is gradually decreased in a direction toward the conductive layer 124, and is gradually increased in a direction away from the conductive layer 124. In detail, in the cross-section of the semiconductor device 30, each portion 116s may have an inverted trapezoidal shape or a stepped structure. In addition, the first semiconductor layer 116 may include a doped region 116a which is in direct contact with the conductive layer 124. In an embodiment, the doped region 116a may include a second dopant and a fourth dopant that is different from the first dopant, the second dopant, and the third dopant. The fourth dopant may be a group II, group IV or group VI element in the periodic table of elements. In an embodiment, the fourth dopant is selected from C, Zn, Si, Ge, Sn, Se, Mg or Te. That is, four different dopants may be included in the epitaxial structure 102 of the semiconductor device 30.

In an embodiment, with respect to the first semiconductor structure 104, the first dopant and the third dopant are of the same conductivity type, the second dopant and the fourth dopant are of the same conductivity type, and the first/third dopants and the second/fourth dopants are of different conductivity types. For example, in an embodiment, the first dopant and the third dopant are n-type dopants, and the second dopant and the fourth dopant are p-type dopants; in another embodiment, the first dopant and the third dopant are p-type dopants, and the second dopant and the fourth dopant are n-type dopants. According to an embodiment, the maximum concentration of the fourth dopant in the first semiconductor layer 116 may be greater than the maximum concentration of the second dopant. Specifically, the fourth dopant in the first semiconductor layer 116 may have a doping concentration of not less than 1×10¹⁸/cm³ or not less than 1×10¹⁹/cm³, such as in the range of 5×10¹⁸/cm³ to 5×10¹⁹/cm³. In this embodiment, the doped region 116a does not overlap with the structure of the first electrode 110 in the vertical direction, thereby the current distribution of the semiconductor device 30 during operation can be improved. The detailed descriptions of positions, relative relationships and material of other layers or structures as well as structural variations in this embodiment can be referred to the foregoing embodiments and are not repeatedly described herein.

FIG. 3A is a graph showing the relationship between concentrations of an element and depths in a portion of a light-emitting device 30 in accordance with an embodiment of the present disclosure.

Specifically, FIG. 3A shows the result of SIMS analysis of a part of the structure in the semiconductor device 30 including the first dopant and the second dopant (for example, it may correspond to the structure along the AA′ line marked in FIG. 2B). As shown in FIG. 3A, a part of the structure of the semiconductor device 30 in this embodiment includes a first semiconductor layer 116, a second semiconductor layer 118, an active region 108 and a third semiconductor layer 120 that are sequentially arranged. In the semiconductor device 30, the first semiconductor layer 116 includes GaP, the second semiconductor layer 118 includes AlInP, the barrier layer 108a and the well layer 108 c2 of the active region 108 both include AlGaInP, the first confinement layer 108a and the second confinement layer 108b include AlGaInP, the third semiconductor layer 120 includes AlInP, and the fourth semiconductor layer 122 includes AlGaInP. In FIG. 3, the curve D1 represents the doping concentration of the first dopant, and the curve D2 represents the doping concentration of the second dopant. In this embodiment, the first dopant is distributed in the range from the first semiconductor layer 116 to the third semiconductor layer 120, and the second dopant is mainly distributed in the range from the first semiconductor layer 116 to the active region 108.

As shown in FIG. 3A, in this embodiment, in the first semiconductor structure 104, the maximum concentration (C1) of the first dopant and the maximum concentration (C2) of the second dopant are located near the interface between the first semiconductor layer 116 and the second semiconductor layer 118. In this embodiment, the maximum concentration (C1) of the first dopant is greater than the maximum concentration (C2) of the second dopant. As shown in FIG. 3A, in the first semiconductor structure 104 of this embodiment, the concentration of the first dopant is greater than or equal to the concentration of the second dopant only in vicinity of the interface between the first semiconductor layer 116 and the second semiconductor layer 118 (approximately within a depth range of ±0.5 nm at the interface of the first semiconductor layer 116 and the second semiconductor layer 118). In the rest part of the first semiconductor structure 104, the doping concentration of the first dopant is less than that of the second dopant. In this embodiment, when the first dopant is an n-type dopant and the second dopant is a p-type dopant, a p-n-p junction may be formed in the first semiconductor structure 104. According to some embodiments, the presence of the p-n-p junction may reduce the capacitance of semiconductor device 30.

FIG. 3B is a graph showing the relationship between concentrations of an element and depths in a portion of a light-emitting device 30 in accordance with an embodiment of the present disclosure. The main difference between the semiconductor device 30 shown in FIG. 3B and the semiconductor device 30 shown in FIG. 3A is that the maximum concentration (C1) of the first dopant is less than the maximum concentration (C2) of the second dopant in the first semiconductor structure 104, and the doping concentration of the first dopant is smaller than the doping concentration of the second dopant in the first semiconductor structure 104. According to some embodiments, the semiconductor device 30 of this structure can have a relatively stable capacitance and a lower forward voltage value at a high frequency (such as in the frequency range of 10⁵ Hz to 10⁷ Hz). For example, according to an embodiment, in the frequency range of 10⁵ Hz to 10⁷ Hz, the difference between the maximum value and the minimum value of the capacitance of the semiconductor device 30 may be less than 5%, such as in the range of 0% to 3%.

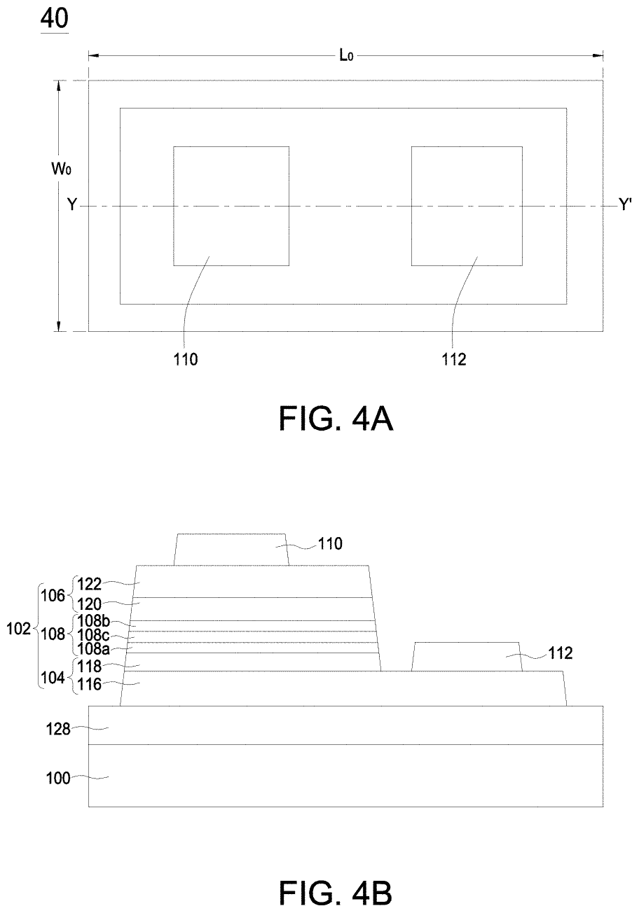

FIG. 4A shows a schematic top view of a semiconductor device 40 in accordance with an embodiment of the present disclosure. FIG. 4B shows a schematic sectional view of the semiconductor device 40 along the line Y-Y′ in FIG. 4A. The main difference between the semiconductor device 40 in this embodiment and the semiconductor device 10 is that the first electrode 110 and the second electrode 112 in the semiconductor device 40 are located on the same side of the base 100, while the first electrode 110 and the second electrode 112 in the semiconductor device 10 are respectively located on two sides of the base 100. In this embodiment, the epitaxial structure 102 is located on the base 100, and the first electrode 110 and the second electrode 112 are located on the epitaxial structure 102. The first electrode 110 can be in direct contact with the second semiconductor structure 106 and the second electrode 112 can be in direct contact with the first semiconductor structure 104. In this embodiment, the widths of the second semiconductor structure 106 and the active region 108 are both less than the width of the first semiconductor structure 104. It should be understood that although FIG. 4A shows that the second semiconductor structure 106 is located on the active region 108 and the first semiconductor structure 104 is located under the active region 108, in another embodiment, the second semiconductor structure 106 may be located under the active region 108 and in direct contact with the base 100, while the first semiconductor structure 104 may be located on the active region 108 and in direct contact with the second electrode 112. The bonding structure 128 is located between the epitaxial structure 102 and the base 100. The bonding structure 128 may include a conductive or non-conductive material. The detailed descriptions of positions, relative relationships and material of other layers or structures as well as structural variations in this embodiment can be referred to the foregoing embodiments and are not repeatedly described herein.

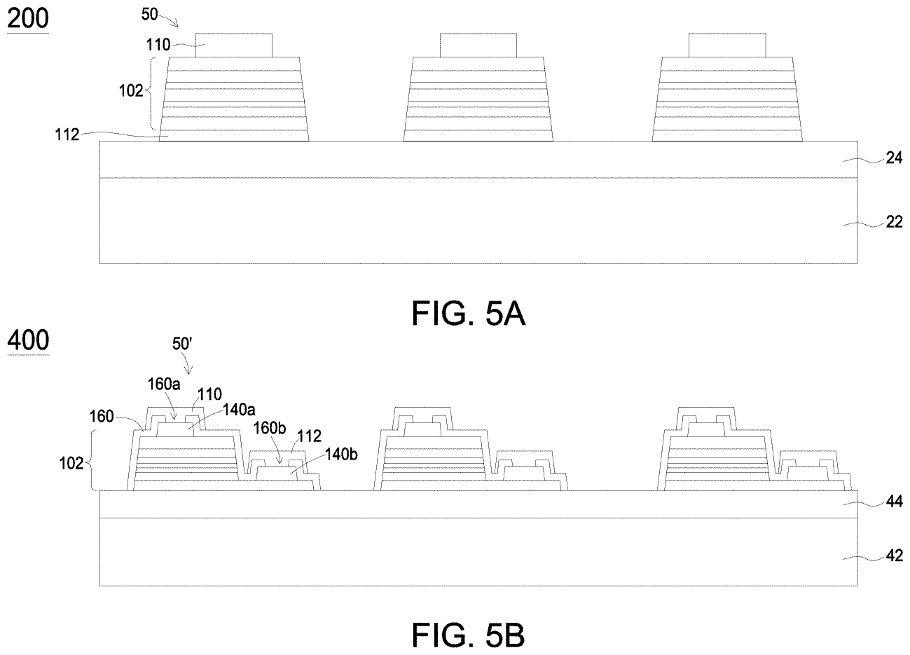

FIG. 5A shows a schematic sectional view of a semiconductor component 200 in accordance with an embodiment of the present disclosure. As shown in FIG. 5A, the semiconductor device 200 includes a carrier substrate 22, an adhesive layer 24 on the carrier substrate 22, and a plurality of semiconductor devices 50 on the adhesive layer 24. In this embodiment, each of the semiconductor devices 50 may include the epitaxial structure 102 described in an embodiment mentioned above, the first electrode 110 and the second electrode 112 which are respectively located on two sides of the epitaxial structure 102. Each semiconductor device 50 does not have the base. The carrier substrate 22 can be connected to the plurality of semiconductor devices 50 through the adhesive layer 24. The carrier substrate 22 may include a conductive material or an insulating material, such as sapphire, glass, gallium arsenide (GaAs), indium phosphide (InP), silicon carbide (SiC), gallium phosphide (GaP), zinc oxide (ZnO), nitride gallium (GaN), aluminum nitride (AlN), germanium (Ge) or silicon (Si). The material of the adhesive layer 24 may include a polymer material, such as benzocyclobutene (BCB), epoxy, polyimide, silicon-based resin (silicone) or SOG (Spin-On-Glass). The detailed descriptions of positions, relative relationships and material of other layers or structures as well as structural variations in this embodiment can be referred to the foregoing embodiments and are not repeatedly described herein.

FIG. 5B shows a schematic sectional view of a semiconductor component 400 in accordance with an embodiment of the present disclosure. As shown in FIG. 5B, the semiconductor component 400 includes a carrier substrate 42, an adhesive layer 44 on the carrier substrate 42, and a plurality of semiconductor devices 50′ on the adhesive layer 44. In this embodiment, each of the semiconductor devices 50′ may include the epitaxial structure 102 described in an embodiment mentioned above, the first electrode 110 and the second electrode 112 which are located on one side of the epitaxial structure 102. Each semiconductor device 50′ does not have the base. For example, there may be no growth substrate between the carrier substrate 42 and the epitaxial structure 102. Each semiconductor device 50′ may further include a first contact structure 140a and a second contact structure 140b. The first contact structure 140a is located between the first electrode 110 and the epitaxial structure 102. The second contact structure 140b is located between the second electrode 112 and the epitaxial structure 102. The first contact structure 140a and the second contact structure 140b may respectively include a single layer or multiple layers of group III-V semiconductor material, metal or alloy. The semiconductor device 50′ further includes a dielectric layer 160 covering the epitaxial structure 102 and having a first opening 160a and a second opening 160b. As shown in FIG. 5B, the first electrode 110 can fill in the first opening 160a and be electrically connected to the first contact structure 140a, and the second electrode 112 can fill in the second opening 160b and be electrically connected to the second contact structure 140b. Regarding the carrier substrate 42 and the adhesive layer 44, reference can be made to the foregoing description of the carrier substrate 22 and the adhesive layer 24. The detailed descriptions of positions, relative relationships and material of other layers or structures as well as structural variations in this embodiment can be referred to the foregoing embodiments and are not repeatedly described herein.

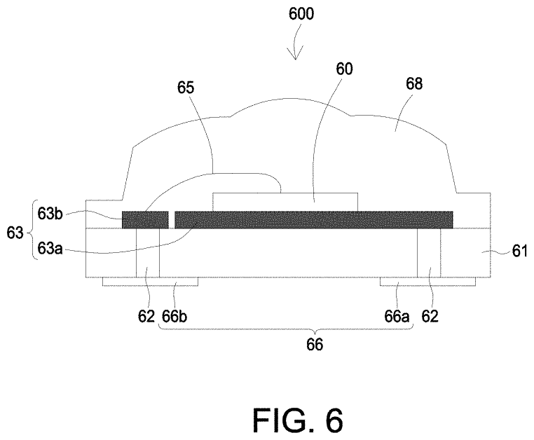

FIG. 6 shows a schematic sectional view of a semiconductor component 600 in accordance with an embodiment of the present disclosure. As shown in FIG. 6, the semiconductor component 600 includes a semiconductor device 60, a package substrate 61, a carrier 63, a bonding wire 65, a contact structure 66 and an encapsulating material 68. The package substrate 61 may include a ceramic or glass. The package substrate 61 has a plurality of through holes 62. Each through hole 62 may be filled with a conductive material such as metal for electrical conduction and/or heat dissipation. The carrier 63 may be located on a surface of one side of the package substrate 61 and may contain a conductive material such as metal. The contact structure 66 is on a surface on another side of the package substrate 61. In the embodiment, the contact structure 66 includes a first contact pad 66a and a second contact pad 66b, and the first contact pad 66a and the second contact pad 66b can be electrically connected to the carrier 63 through the through holes 62. In an embodiment, the contact structure 66 may further include a thermal pad (not shown), for example, between the first contact pad 66a and the second contact pad 66b.

The semiconductor device 60 is located on the carrier 63 and may be the semiconductor device as described in any embodiment of the present disclosure (such as the semiconductor devices 10, 20, 30, 40, 50, 50′ and variations thereof). In the embodiment, the carrier 63 includes a first portion 63a and a second portion 63b, and the semiconductor device 60 is electrically connected to the second portion 63b of the carrier 63 by a bonding wire 65. The material of the bonding wire 65 may include metal, such as gold (Au), silver (Ag), copper (Cu), or aluminum (Al), or may include alloy containing one or more of the above metals. The encapsulating material 68 covers the semiconductor device 60 and protects the semiconductor device 60. Specifically, the encapsulating material 68 may include a resin material, such as an epoxy resin, or a silicone resin. The encapsulating material 68 may further include a plurality of wavelength conversion particles (not shown) to convert a first light emitted by the semiconductor device 60 into a second light. The wavelength of the second light is greater than the wavelength of the first light.

Based on the above, an epitaxial structure, a semiconductor device or a semiconductor component can be provided in the present disclosure. For example, by adjusting dopant concentrations in the epitaxial structure, improved optical-electrical characteristics, such as capacitance or forward voltage, may be provided. Specifically, the epitaxial structure, the semiconductor device or the semiconductor component of the present disclosure can be applied to products in various fields, such as illumination, medical care, display, communication, sensing, or power supply system, for example, can be used in a light fixture, monitor, mobile phone, tablet, an automotive instrument panel, a television, computer, wearable device (such as watch, bracelet or necklace), traffic sign, outdoor display device, or medical device.

It should be realized that each of the embodiments mentioned in the present disclosure is used for describing the present disclosure, but not for limiting the scope of the present disclosure. Any obvious modification or alteration is not departing from the spirit and scope of the present disclosure. Furthermore, embodiments can be combined or substituted under proper condition and are not limited to specific embodiments described above. A connection relationship between a specific component and another component specifically described in an embodiment can also be applied in another embodiment and is within the scope as claimed in the present disclosure.

What is claimed is:

1. A semiconductor device, comprising:
a first semiconductor structure comprising a first semiconductor layer including a first dopant and a second dopant;
a second semiconductor structure located on the first semiconductor structure and including the first dopant; and
an active region located between the first semiconductor structure and the second semiconductor structure and including the first dopant;
wherein the first dopant and the second dopant have different conductivity types.

2. The semiconductor device of claim 1, wherein the first dopant has a first maximum concentration (C1) in the first semiconductor structure, the second dopant has a second maximum concentration (C2) in the semiconductor structure, and the second maximum concentration (C2) is greater than the first maximum concentration (C1).

3. The semiconductor device of claim 2, wherein the concentration of the second dopant is greater than the concentration of the first dopant throughout the first semiconductor structure.

4. The semiconductor device of claim 2, wherein the first dopant has a third maximum concentration (C3) in the active region, and the third maximum concentration (C3) is greater than, less than or equal to the first maximum concentration (C1).

5. The semiconductor device of claim 1, wherein the first semiconductor layer has an upper surface with a roughened structure.

6. The semiconductor device of claim 1, wherein the first dopant is an n-type dopant, and the second dopant is a p-type dopant.

7. The semiconductor device of claim 1, wherein the first semiconductor layer includes a binary group III-V semiconductor material.

8. The semiconductor device of claim 1, wherein the first dopant comprises C, Zn, Si, Ge, Sn, Se, Mg or Te.

9. The semiconductor device of claim 2, wherein the second semiconductor structure comprises a second semiconductor layer, the first dopant has a fourth maximum concentration (C4) in the second semiconductor layer, and the fourth maximum concentration (C4) is greater than the first maximum concentration (C1).

10. The semiconductor device of claim 9, wherein the second semiconductor layer and the first semiconductor layer have different conductivity types.

11. The semiconductor device of claim 1, wherein the first semiconductor structure further includes a super lattice structure.

12. The semiconductor device of claim 1, wherein the active region includes a plurality of semiconductor stacks, and each semiconductor stack include a well layer and a barrier layer.

13. The semiconductor device of claim 12, wherein the well layer has a first Al content percentage and the barrier layer has a second Al content percentage greater than the first Al content percentage.

14. The semiconductor device of claim 12, wherein the barrier layer has a first thickness and the well layer has a second thickness less than the first thickness.

15. The semiconductor device of claim 12, wherein the active region further includes a first confinement layer and a second confinement layer, and the plurality of semiconductor stacks is located between the first confinement layer and the second confinement layer.

16. The semiconductor device of claim 15, wherein the barrier layer has a first thickness, and the first confinement layer has a third thickness greater than the first thickness.

17. The semiconductor device of claim 15, wherein the well layer has a first Al content percentage, and the first confinement layer has a third Al content percentage greater than the first Al content percentage.

18. The semiconductor device of claim 1, wherein the second semiconductor structure further includes a third dopant different from the first dopant and the second dopant.

19. The semiconductor device of claim 1, wherein the first semiconductor layer further includes a doped region which includes a fourth dopant different from the first dopant and the second dopant.

20. The semiconductor device of claim 18, wherein the first semiconductor layer further includes a fourth dopant and the first dopant, the second dopant, the third dopant and the fourth dopant are different.
